(19) United States
(12) Patent Application Publication
(10) Pub. No.: US 2014/0204505 A1
(43) Pub. Date: Jul. 24, 2014

(54) Display Device

(71) Applicant: Turi Altavilla, Los, CA (US)

(72) Inventor: Turi Altavilla, Los, CA (US)

(21) Appl. No.: 13/747,676

(22) Filed: Jan. 23, 2013

(51) Int. Cl. H05K 7/00

(52) U.S. Cl. CPC H05K 7/00
USPC 361/679.01; 29/428

(57) ABSTRACT

An advertising device and method of advertising are disclosed for use in a sporting arena and particularly areas in which player impact may occur. The advertising device may include an electronic display for presentation of information in visual form, padding associated with the display, and a fastener for attaching the advertising device to a post where player impact may occur such as a boxing ring corner post, a football goal post, or basketball stanchion. The disclosed advertising devices advantageously multiply advertising real estate in locations where it was previously not possible to do so. Moreover, in the event of impact, the disclosed advertising devices maintain their integrity while also providing player safety.

### CROSS-REFERENCE TO RELATED APPLICATION

The present application claims benefit of and priority to U.S. Provisional Patent Application Ser. No. 61/591,177 filed on Jan. 26, 2012 entitled “Lighted Ring/Cage Corner Pad,” the entire contents of which are hereby incorporated by reference herein.

### BACKGROUND

The field of the present invention generally relates to display devices and more particularly to advertising devices for use in a sporting venue.

Advertising is a critical component of broadcast both in the viewing experience as well as in revenue generation. From the earliest days of television, highly viewed programming has demanded higher advertising fees. Simply put, the more popular a program, the more revenue generated for producers and the more ways that producers look to sell more advertising inventory innovatively.

Look no further than the sports industry. Leagues such as the National Basketball Association, National Football League, National Hockey League, National Collegiate Athletic Association, Major League Baseball, and the Ultimate Fighting Championship all run on similar models. Sponsors support teams (and the league) through the purchase of television commercials as well as the purchasing of real estate within the field of play.

For decades, sports franchises have continued to innovate in creating ad inventory and generating ad revenue. From corporate naming rights for arenas to company logos on jerseys, just about any location is fair game. However, one area of real estate has proven to be very limiting—areas in which player impact may occur. Consider areas such as the corner pad of a boxing ring or mixed martial arts cage, the padding of a football goal post, or the padding on a basketball stanchion. These areas require padding to protect athletes, as safety is the main priority. Advertising in these areas has thus been limited. Indeed, if there is any advertising at all on these padded areas, it consists of some type of printed vinyl lettering or logo. Such a conventional approach is static, restrictive, inefficient, and outdated.

Accordingly, an advertising display device solving the aforementioned problems is therefore desired.

### SUMMARY

One exemplary embodiment of the disclosed subject matter is an advertising device having an electronic display for presentation of information in visual form, padding associated with the display, and a fastener for attaching the advertising device to a post. Should the padding be disposed about the front of the electronic display where the visual information is being presented, then the padding is preferably a clear rugged material and most preferably a clear, shock absorbing material. Should the padding be disposed about the back of the electronic display, then it is preferably a high impact foam.

An advertising device in accordance with an embodiment of the present application may also include a back panel disposed at the back of the electronic display. In such an arrangement, a fastener in the form of straps may be associated with the back panel to attach the advertising device to a post.

Another aspect of the disclosed embodiments includes having an electronic display that is curved, flexible, or both. Where the electronic display does not have front padding, then the electronic display is preferably a flexible organic light-emitting diode display (“OLED”) such as Samsung's Youm™ active-matrix organic light-emitting diode (“AMOLED”) display.

The electronic display may further comprise a power source operable to power the display, and preferably does so without the need for wires such as via battery, solar cell technology, or the like. The display may also have a memory element operable to store information for display on the electronic display. Alternatively, or in combination with a memory element, the electronic display may include a receiver device operable to receive information to be displayed on the electronic display.

In yet another aspect of the disclosed inventions, the advertising device may also have a clear panel disposed about the front of the electronic display. Padding may optionally be disposed about the clear panel opposite the display.

Another exemplary embodiment of the disclosed subject matter is a method of advertising comprising locating a padded post in a sporting arena, attaching a video display to the padded post, and displaying one or more images on the video display. The padded post is preferably a football goal post, a basketball stanchion, a boxing ring corner post, or a mixed martial arts ring post. The video display may be a flexible OLED display, a curved liquid crystal display (“LCD”), or other output device for presentation of information in visual form. A clear panel and visco-elastic polymer padding may be disposed about the video display. The video display may also include a power source operable to power the display wirelessly. The video display may further be in communication with a memory device that stores the images to be displayed on the video display.

### BRIEF DESCRIPTION OF THE DRAWINGS

Some non-limiting exemplary embodiments of the disclosed subject matter are illustrated in the following drawings. Identical or duplicate or equivalent or similar structures, elements, or parts that appear in one or more drawings are generally labeled with the same reference numeral, optionally with an additional letter or letters to distinguish between similar objects or variants of objects, and may not be repeatedly labeled and/or described. Dimensions of components and features shown in the figures are chosen for convenience or clarity of presentation. For convenience or clarity, some elements or structures are not shown or shown only partially and/or with different perspective or from different point of views.

FIG. 1 is a perspective view of an embodiment of the inventions disclosed herein in a mixed martial arts sporting arena;

FIG. 2 is a perspective view of an embodiment of the inventions disclosed herein in a basketball sporting arena;

FIG. 3 is a perspective view of an embodiment of the inventions disclosed herein in a football sporting arena;

FIG. 4A is a close-up view of an embodiment of the inventions disclosed herein in a mixed martial arts sporting arena;

FIG. 4B is a close-up view of an embodiment of the inventions disclosed herein in a boxing sporting arena;

FIG. 5 is an exploded view of the embodiment illustrated in FIG. 4B;

FIG. 6 is a close-up view of an embodiment of the inventions disclosed herein in a football sporting arena;

FIG. 7 is an exploded view of the embodiment illustrated in FIG. 6 showing certain exemplary aspects thereof;

FIG. 8 is a perspective view of the embodiment illustrated in FIG. 6 showing certain exemplary aspects thereof;

FIG. 9 is a representative top view of the embodiment illustrated in FIG. 6 showing certain exemplary aspects thereof;

FIG. 10 is an exploded view of an embodiment of the inventions disclosed therein showing certain exemplary aspects thereof;

FIG. 11A is an exploded view of an embodiment of the inventions disclosed therein showing certain exemplary aspects thereof.

FIG. 11B is a front view of the embodiment illustrated in FIG. 11A showing certain exemplary aspects thereof;

FIG. 12A is an exploded view of an embodiment of the inventions disclosed therein showing certain exemplary aspects thereof.

FIG. 12B is a perspective view of the embodiment illustrated in FIG. 12A showing certain exemplary aspects thereof;

FIG. 13A is an exploded view of an embodiment of the inventions disclosed therein showing certain exemplary aspects thereof;

FIG. 13B is a view of the embodiment illustrated in FIG. 13A showing how such embodiment may be attached to a preexisting pad that in turn may be attached to a post in a sporting arena; and

FIG. 14 is a top view of an embodiment of the inventions disclosed therein showing certain exemplary aspects thereof.

### DETAILED DESCRIPTION

A general problem in the field of advertising displays in a sporting arena is the limited form of communication (variety, quantity, style) in areas in which player impact may occur. A general solution is an electronic display operable to present varying forms of information, wherein the electronic display is placed in an area in which player impact may occur.

A technical problem in the field of advertising displays in a sporting arena and particularly areas in which player impact may occur is the conventional inability to vary the form of communication on the display while also maintaining player safety. A technical solution implementing the spirit of the disclosed inventions is a video display that may be padded and attachable to a post where player impact may occur such as a boxing ring corner post, a football goal post, or basketball stanchion.

Potential benefits of the general and technical solutions provided by the disclosed subject matter include the presentation of full-motion graphics and the ability to change and update messaging. In terms of showmanship and spectacle, the uses of the inventions disclosed herein are numerous. For example, during player introductions of a National Basketball Association game, a player's face, likeness, or number could be shown on one of the disclosed inventions disposed underneath each basket. Indeed, the disclosed inventions would offer tremendous enhancements to the spectacle and pageantry of events, only limited by the imagination of its users. As incredible as these benefits are, more important is the advertising inventory that the disclosed inventions create. In particular, the novel inventions herein multiply existing real estate and thus multiply advertising revenue. For example, currently the padding underneath the hoop on each basketball stanchion is capable of only static advertisement. The disclosed subject matter will allow that same space to be multiplied and used for sponsors as many times as desired. This previously static and extremely limited real estate within the field of play is considered absolutely prime in the sports industry. Unlike commercials, one cannot fast forward through the signage in such prime real estate without missing the entertainment of the game itself. Thus, the disclosed inventions present a wealth of benefits to advertisers, teams, and sports leagues.

A general nonlimiting overview of practicing the present disclosure is presented below. The overview outlines exemplary practice of embodiments of the present disclosure, providing a constructive basis for variant and/or alternative and/or divergent embodiments, some of which are subsequently described.

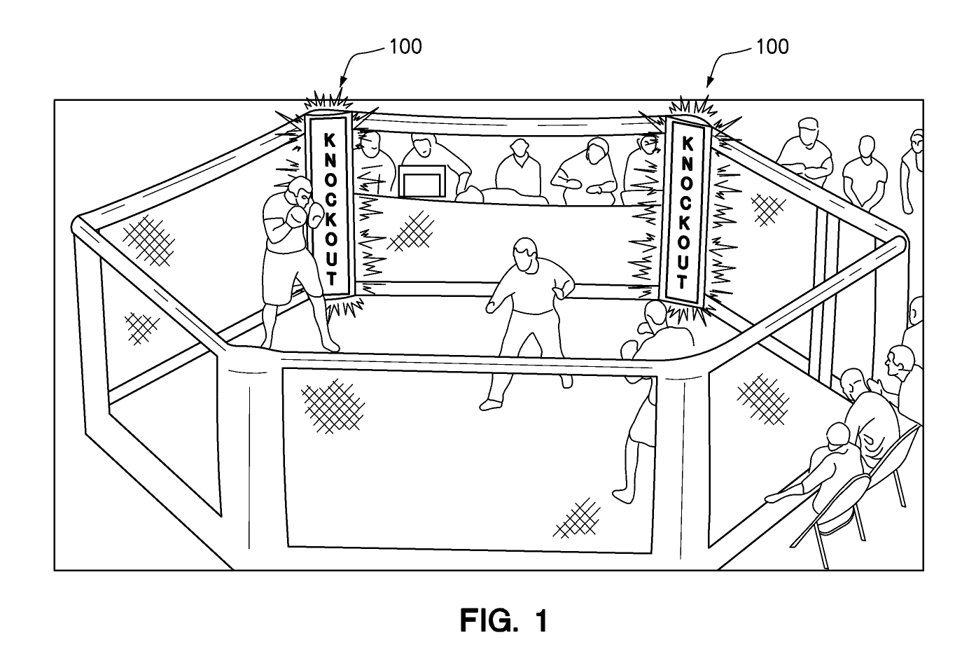

FIG. 1 illustrates a perspective view of an embodiment of the inventions disclosed herein in a mixed martial arts sporting arena. As seen in FIG. 1, advertising device 100 may be seen with the indicia “KNOCKOUT!” thereon. As the advertising device 100 disclosed herein may advantageously be changed or updated, the image shown on the device 100 need not be “KNOCKOUT” but any desired image.

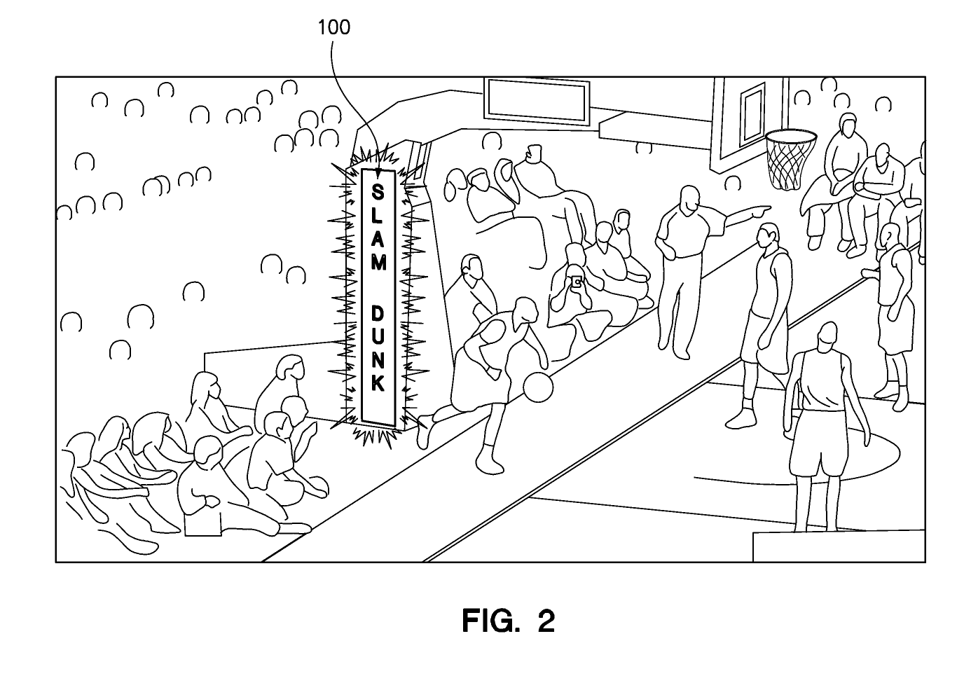

FIG. 2 shows one of the disclosed inventions 100 disposed on the lower portion of a basketball stanchion, a valuable piece of real estate previously constrained in terms of advertising communication before the present inventions. As seen in FIG. 2, advertising device 100 has the image “SLAM DUNK!” thereon but any image may be possible.

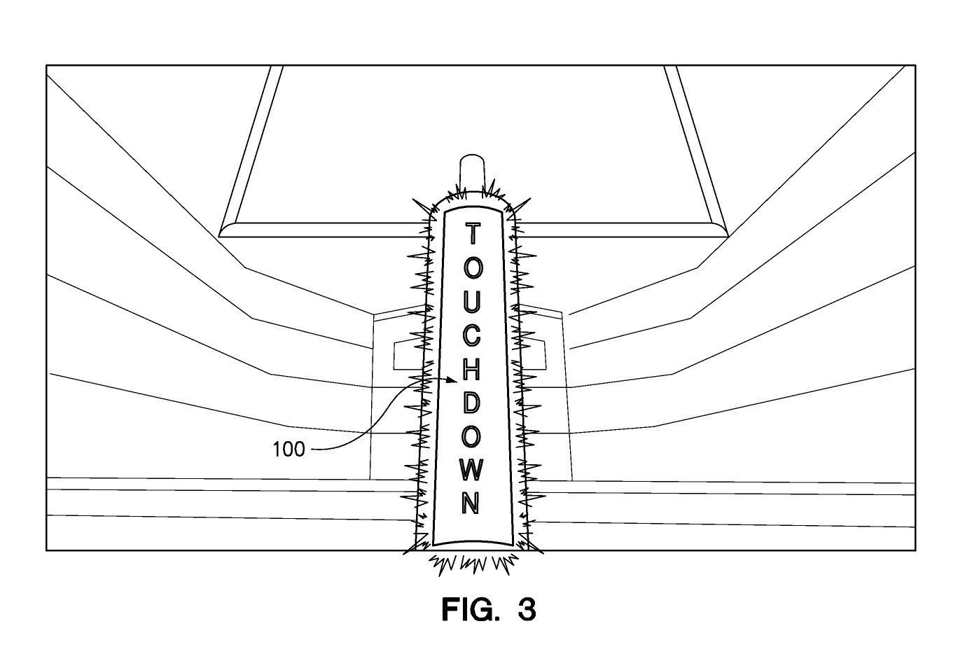

FIG. 3 illustrates one aspect of the disclosed inventions for use with a football goal post. The advertising display 100 seen in FIG. 3 shows “TOUCHDOWN” thereon but other images may be present.

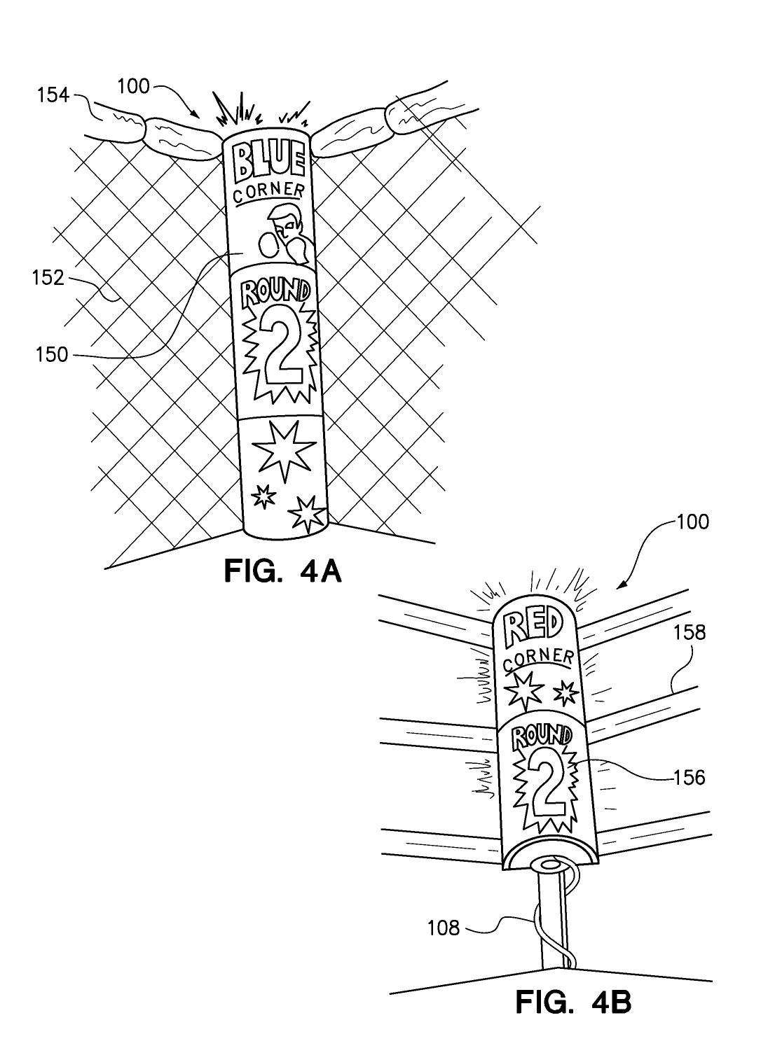

FIG. 4A is a close-up view of an embodiment of the inventions disclosed herein in a mixed martial arts sporting arena. As seen in FIG. 4A, advertising device 100 has images 150 thereon. The device 100 is disposed about a corner post of a mixed martial arts cage comprising fencing 152 and cover pad 154.

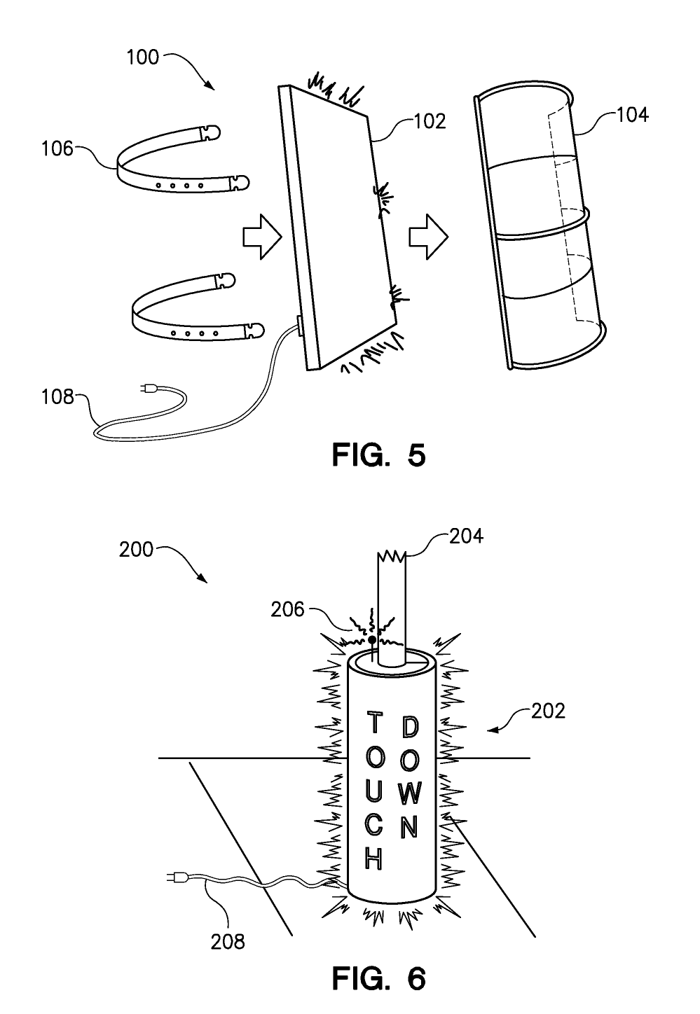

FIGS. 4B and 5 illustrate an embodiment of the inventions disclosed herein in a boxing sporting arena. As seen in FIG. 4B, advertising device 100 has images 156 thereon. The device 100 is disposed about a corner post of a boxing ring having boxing ropes 158.

Turning in detail to the advertising device 100 shown in FIG. 4B, the advertising device 100 may comprise an electronic display 102, padding 104, a fastener 106 to attach the device 100 to a post, and a power source 108.

The display 102 is preferably an output device for presentation of information in visual form. When the input information is supplied as an electrical signal, the display is typically referred to as an electronic display as is the case with display 102. With this foundation, it is understood that display 102 may be a television, computer monitor, or the like. The display 102 is preferably a liquid crystal display (“LCD”) device, an LED device, an OLED device, an AMOLED device, or the like.

The electronic display 102 may be curved, flexible, or both. A curved LCD display has already been developed by the Centre of Microsystems Technology, and such technology or similar technology may be employed to make the electronic display 102. Instead of using LCD technology, the electronic display may preferably be a flexible OLED device such as Samsung's Youm™ AMOLED device.

The padding 104 is preferably a clear material and may even be clear vinyl. However, the padding 104 is most preferably a clear, shock absorbing material. To this end, the front padding may be made of a shock absorbing polymer, a visco-elastic polymer, or a visco polymer. Such materials may include rubber, neoprene, silicone, and most preferably Sorbothane®, the latter of which is a proprietary, visco-elastic polymer and particularly a thermoset, polyether-based, polyurethane material.

FIG. 5 illustrates fastener 106 may be a strap coupled to the back of the electronic display 102. However, fastener 106 may be other conventional attachment means including a hook and loop arrangement, rope, string, wire, cable, chain, plastic wrap, a crimping arrangement, a welding arrangement, a brazing arrangement, tape, glue, cement, or the like.

Power source 108 is illustrated in FIG. 5 as a power cord connectable to a typical AC source, if desired. Alternatively, power source 108 may be in the form of a battery, rechargeable or otherwise, or any other portable voltage or current source, wherein the display 102 may be operated wirelessly. For example, the power source 108 may use solar cell technology if the sporting arena in which the advertising device 100 is used is outdoors. The electronic display 102 may even be wirelessly powered by the use of wireless power technology disclosed by one or more of the following United States patents, each of which is incorporated by reference as if fully disclosed herein: 6,289,237; 6,615,074; 6,856,291; 7,027,311; 7,057,514; 7,084,605; 7,373,133; 7,383,064; 7,403,803; 7,440,780; 7,567,824; 7,639,994; and 7,643,312.

FIGS. 6-9 illustrate an embodiment of the inventions disclosed herein in a football sporting arena. As seen in FIG. 6, advertising device 200 has been attached to a football goal post 204. FIG. 6 shows the advertising device 200 as having a display 202, receiver device 206, and power source 208. The display 200 may be an electronic display such as those described above. In the context of FIGS. 6-9, the display 200 is preferably an OLED device. The receiver device 206 is illustrated as a WiFi receiver. However, receiver device 206 may be any conventional means of receiving information wirelessly such as a local area network arrangement, wide area network arrangement, or the like. The power source 208 is again illustrated as a power cord but other power means such as those described above may be employed.

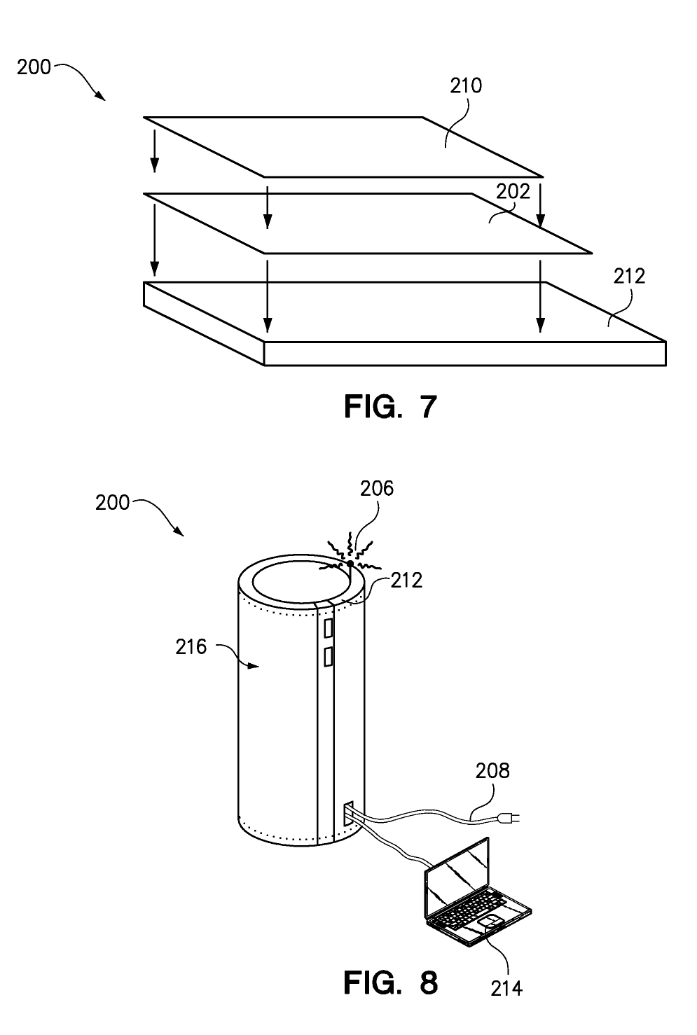

As seen in FIG. 7, advertising device 200 may include padding 212 disposed between the display 202 and post 204 (not shown). This inner padding 212 may be formed from high impact foam, preferably a visco-elastic polyurethane foam or low-resilience polyurethane foam, that is three to four inches thick. Padding 212 is preferably encased in 18 ounce vinyl covering that is sewn and stitched to fit. The display 202 should be large enough to cover most of the exposed outer area of the inner padding 212.

Advertising device 200 may also include a clear panel 210 disposed about the front of the display 202 that will emit the information to be seen by a crowd at a sporting event, for example. Here, the clear panel 210 is opposite the padding 202 disposed between the display 202 and post 204 (not shown). This inner padding may be a clear, matte polyvinyl chloride (“PVC”) sheet that is stitched upon the outer area of the inner padding 212 not covered by the display 202.

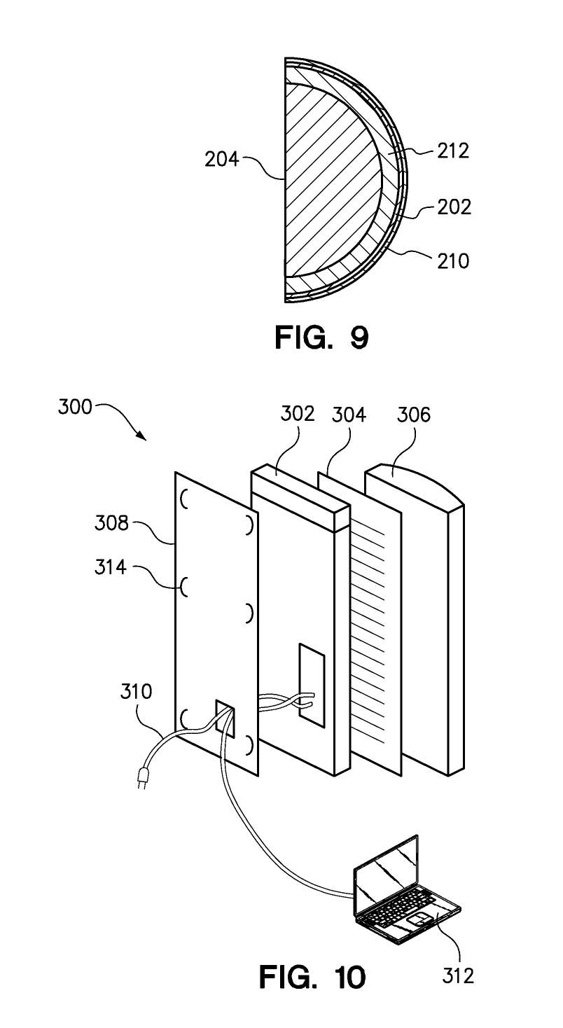

As seen in FIG. 8, advertising device 200 may be secured and attached to post 204 (not shown) via one or more fasteners. Fasteners 216 are illustrated in FIG. 8 as a hook and loop arrangement. FIG. 8 also shows that computer hardware 214, such as a memory device and/or logic hardware, may be associated with the advertising device 200. Such hardware 214 may operate to allow information stored thereon or dynamically provided thereto to be displayed on display 202. FIG. 9 is a partial top view of advertising device 200 that illustrates how the device 204 would look as attached to a post 204.

FIG. 10 is an exploded view of an embodiment of the inventions disclosed therein showing certain exemplary aspects thereof. As seen in FIG. 10, advertising device 300 may include a display 302, a clear panel 304 disposed about the front of the display 302, padding 306 disposed about the clear panel 304, a back panel 308 disposed about the back of the display 302, a power source 310 to power the device 300, and computer hardware 312 that may serve to help operate the device 300.

The display 302 may be an electronic display such as those described above. In the context of FIG. 10, the display 302 is preferably an LCD device. The clear panel 304 may be a thin panel such as a Plexiglas® sheet, a Lexan® sheet, or Gorilla® glass. The padding 306 is preferably clear and made from a visco-elastic polymer as described above. The back panel 308 may be a steel backplate that has hooks 314 for associating with a fastener (not shown), such as a strap, to be inserted therethrough. The fasteners will allow the advertising device 300 to be attached to a post in a sporting arena as described above. The power source 310 is illustrated as a power cord but other power means such as those described above may be employed. Computer hardware 312 is representative in that the advertising device 300 may use a typical computer, memory device, and/or logic board to store and display information to the display, or the device 300 may use a wireless arrangement as discussed above, or a combination thereof.

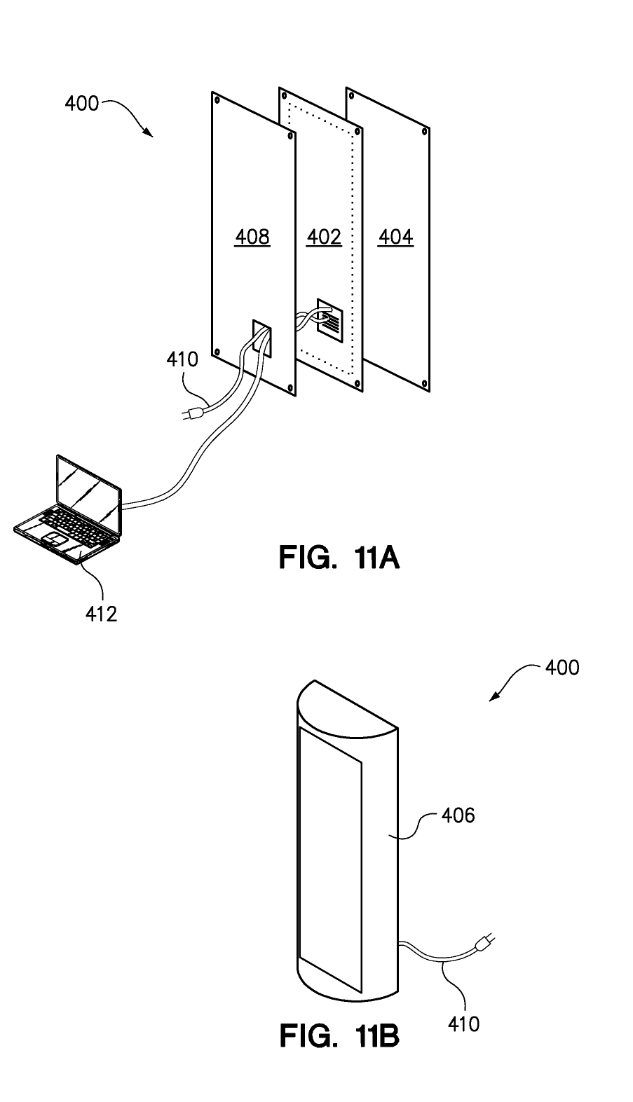

FIGS. 11A and 11B illustrate an embodiment of the inventions disclosed therein showing certain exemplary aspects thereof. As seen in FIGS. 11A and 11B, advertising device 400 may include a display 402, a clear panel 404 disposed about the front of the display 402, and a back panel 408 disposed about the back of the display 402. These three components 402, 404, and 408 are preferably screwed together to create one unit to which padding 406 is added. In particular, the unit comprised of 402, 404, and 408 is preferably encased in optical silicone molding or other clear visco-elastic polymer as described above.

The display 402 may be an electronic display such as those described above. In the context of FIGS. 11A and 11B, the display 402 is preferably an OLED device. The clear panel 404 may be a thin panel such as a Plexiglas® sheet, a Lexan® sheet, or Gorilla® glass. The back panel 408 may be made of a hard plastic or steel. Fasteners (not shown) allow the advertising device 400 to be attached to a post in a sporting arena as described above.

As seen in FIG. 11A, advertising device 400 may also include a power source 410 to power the device 400, as well as computer hardware 412 that may serve to help operate the device 400. The power source 410 is illustrated as a power cord but other power means such as those described above may be employed. Hardware 412 is representative in that the advertising device 400 may use computer hardware such as a memory device and/or logic board to store and display information to the display, or the device 400 may use a wireless arrangement as discussed above, or a combination thereof.

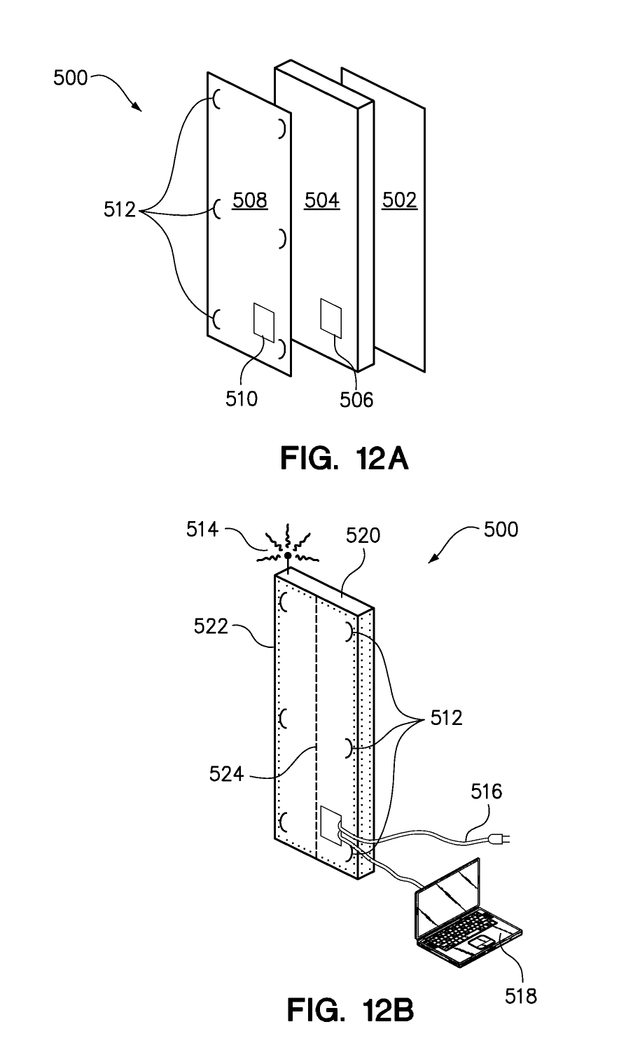

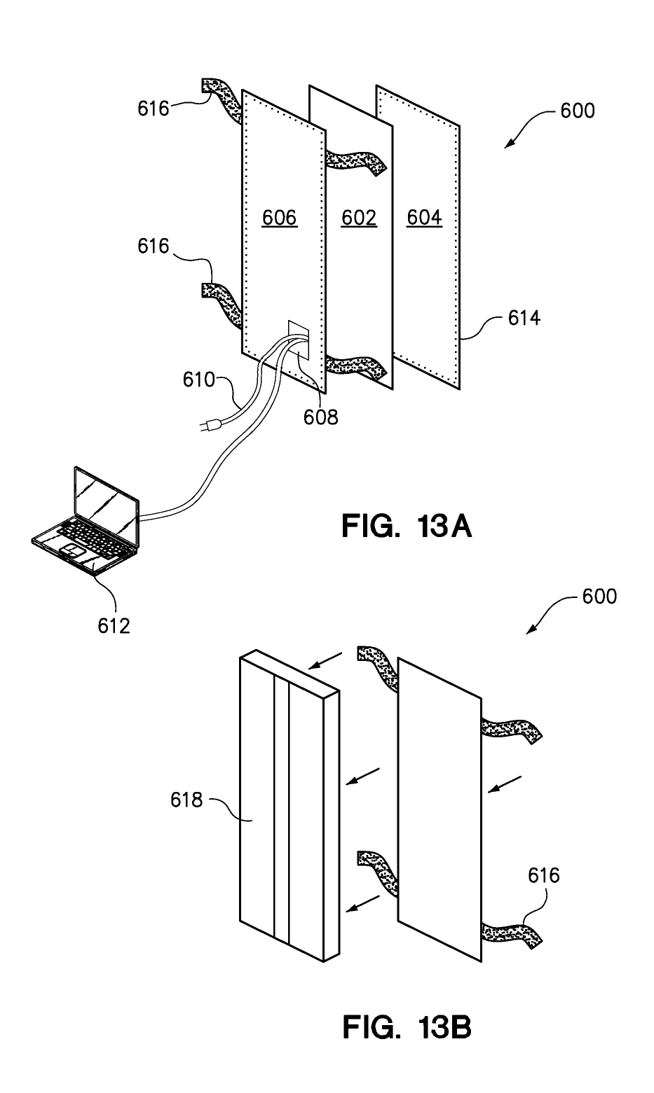

FIGS. 12A and 12B illustrate an embodiment of the inventions disclosed therein showing certain exemplary aspects thereof. As seen in FIG. 12A, advertising device 500 may include an electronic display 502, inner padding 504 disposed about the back of the display 502, and a back panel 508 disposed about the back of the padding 504. Display 502, padding 504, and back panel 510 may be inserted into a casing 520 that is stitched together via stitching 522. A zipper 524 exists to access components contained within the casing 520. The casing is preferably made of 18 ounce vinyl of any color, except for the front that may be a clear, matte vinyl to permit viewing of images displayed on the display 502.

The display 502 may be an electronic display such as those described above. In the context of FIGS. 12A and 12B, the display 502 is preferably an OLED device. The padding 504 may be made of a high impact foam and preferably a visco-elastic polyurethane foam or low-resilience polyurethane foam. Cutouts 506 and 510 in the padding 504 and back panel 508, respectively, permit access for a power source 516 or computer hardware 518 cables as seen in FIG. 12B. The back panel 508 may be plastic or steel backplate with hooks 512 for associating with a fastener (not shown), such as a strap, to be inserted therethrough. The fasteners will allow the advertising device 500 to be attached to a post in a sporting arena as described above. The power source 516 is illustrated as a power cord but other power means such as those described above may be employed. Hardware 518 is representative in that the advertising device 500 may use computer hardware such as a memory device and/or logic board to store and display information to the display, or the device 500 may use a wireless arrangement 514 as discussed above, or a combination thereof.

FIGS. 13A and 13B illustrate an embodiment of the inventions disclosed therein showing certain exemplary aspects thereof. As seen in FIG. 13A, an advertising device 600 may include an electronic display 602, a clear panel 604 disposed about the front of the display 602, and a back panel 606 disposed about the back of the display 602. These three components 602, 604, and 606 are preferably stitched together to create one unit to be attached to preexisting padding 618 disposed about a post in a sporting arena.

The display 602 may be an electronic display such as those described above. In the context of FIGS. 13A and 13B, the display 602 is preferably an OLED device. Panel 604 may be a clear, matte PVC sheet. The back panel 606 may be made of 18 ounce vinyl of any color. The back panel has fasteners 616 to allow the advertising device 600 to attach to a post with preexisting padding 618.

As seen in FIG. 13A, advertising device 600 may also include a power source 610 to power the device 600, as well as computer hardware 612 that may serve to help operate the device 600. The power source 610 is illustrated as a power cord but other power means such as those described above may be employed. Hardware 612 is representative in that the advertising device 600 may use computer hardware such as a memory device and/or logic board to store and display information to the display, or the device 600 may use a wireless arrangement as discussed above, or a combination thereof.

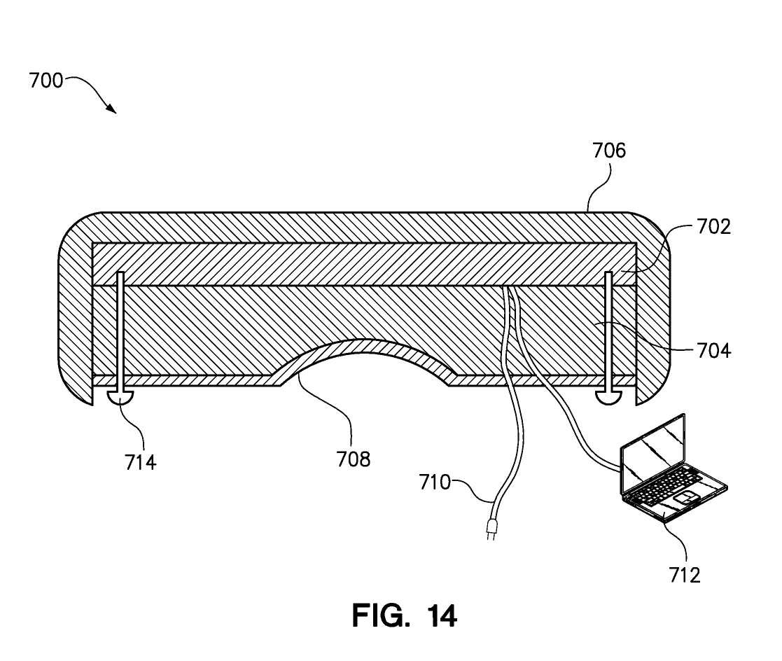

FIG. 14 is a top view of an embodiment of the inventions disclosed therein showing certain exemplary aspects thereof. As seen in FIG. 14, advertising device 700 may include an electronic display 702, a clear panel 706 preferably made of a visco-elastomeric polymer to protect the front and sides of the display 702, padding 704 disposed about the back of display 702, and a back panel 408 disposed about the back of padding 704. These three components 702, 704, and 708 are preferably screwed together via screws 714.

The display 702 may be an electronic display such as those described above. In the context of FIG. 14, the display 702 is preferably an LED device. The padding 704 may be formed from high impact foam, preferably a visco-elastic polyurethane foam or low-resilience polyurethane foam. The back panel 708 may be made of steel with holes formed therein to allow entry of the screws 714. One or more fasteners (not shown) allow the advertising device 700 to be attached to a post in a sporting arena as described above. The advertising device 700 may also include a power source 710 to power the device 700, as well as computer hardware 712 that may serve to help operate the device 700. The power source 710 is illustrated as a power cord but other power means such as those described above may be employed. Hardware 712 is representative in that the advertising device 700 may use computer hardware such as a memory device and/or logic board to store and display information to the display, or the device 700 may use a wireless arrangement as discussed above, or a combination thereof.

Another exemplary embodiment of the disclosed subject matter is a method of advertising comprising locating a padded post in a sporting arena, attaching a video display such as display 602 in FIG. 13A to the padded post, and displaying one or more images on the video display. The padded post is preferably a football goal post, a basketball stanchion, a boxing ring corner post, or a mixed martial arts ring post. The video display may be a flexible OLED device, a curved LCD device, or other output device for presentation of information in visual form as discussed above. A clear panel, such as panel 604 in FIG. 13A, may be disposed about the video display. A visco-elastic polymer padding, such as padding 706 seen in FIG. 14, may optionally be disposed about the video display. The video display may also include a power source operable to power the display wirelessly, as discussed above. Moreover, the video display may also be in communication with a memory device that stores the images to be displayed on the video display, as discussed above.

In light of the above disclosure, it is apparent that the advertising devices and methods disclosed herein advantageously multiply advertising real estate in locations where it was previously not possible to do so. Moreover, in the event of impact, the disclosed advertising devices maintain their integrity while protecting those who might collide with the devices such as a player in a sporting event.

While certain embodiments have been described, the embodiments have been presented by way of example only and are not intended to limit the scope of the inventions. Indeed, the novel devices and methods described herein may be embodied in a variety of other forms; furthermore, various omissions, substitutions, and changes in the form of the devices and methods described herein may be made without departing from the spirit of the inventions. For example, techniques, systems, subsystems, and methods described and illustrated in the various embodiments as discrete or separate may be combined or integrated with other systems, modules, techniques, or methods without departing from the scope and spirit of the present disclosure. Other items shown or discussed as coupled or directly coupled or communicating with each other may be indirectly coupled or communicating through some interface, device, or intermediate component whether electrically, mechanically, or otherwise. The accompanying claims and their equivalents are intended to cover such forms or modifications as would fall within the scope and spirit of the inventions.

Indeed, none of the description in the present application should be read as implying that any particular element, step, or function is an essential element that must be included in the claim scope. In contrast, the scope of the patented subject matter is defined only by the allowed claims. Moreover, none of thee is claims is intended to invoke paragraph six of 35 U.SC. section 112 unless the exact words “means for” are followed by a participle. The claims as filed as intended to be as comprehensive as possible, and no subject matter is intentionally relinquished, dedicated, or abandoned.

1. An advertising device comprising:
an electronic display for presentation of information in visual form, wherein the display has a front and back, and wherein the front of the display is where information is to be presented;
padding disposed about the front or the back of the display; and
a fastener to attach the advertising device to a post.

2. The advertising device of claim 1, wherein the padding is disposed at the front of the electronic display.

3. The advertising device of claim 2, wherein the padding comprises a clear, visco-elastic polymer.

4. The advertising device of claim 2 further comprising a second padding disposed at the back of the electronic display.

5. The advertising device of claim 4, wherein the second padding comprises a high impact foam.

6. The advertising device of claim 1 further comprising a back panel disposed at the back of the electronic display, and wherein the fastener comprises straps associated with the back panel.

7. The advertising device of claim 1, wherein the electronic display is a curved liquid crystal display.

8. The advertising device of claim 1, wherein the electronic display is flexible.

9. The advertising device of claim 1, wherein the electronic display further comprises a power source operable to power the display without wires.

10. The advertising device of claim 1, wherein the electronic display further comprises a memory element operable to store information for display on the electronic display.

11. The advertising device of claim 1, wherein the electronic display further comprises a receiver device operable to receive information for display on the electronic display.

12. The advertising device of claim 1 further comprising a clear panel disposed between the front of the electronic display and the padding, wherein the electronic display is a liquid crystal display.

13. A method of advertising comprising:
locating a padded post in a sporting arena, wherein the padded post is selected from the group consisting of a football goal post, a basketball stanchion, a boxing ring corner post, and a mixed martial arts ring post;
attaching a video display to the padded post; and
displaying one or more images on the video display.

14. The method of advertising of claim 13, wherein the video display is a flexible organic light-emitting diode display.

15. The method of advertising of claim 13, wherein the video display is curved.

16. The method of advertising of claim 15 further comprising disposing a clear panel and a clear visco-elastic polymer padding about the curved display where the one or more images are to be displayed.

17. The method of advertising of claim 13, wherein the video display further comprises a power source operable to power the display wirelessly.

18. The method of advertising of claim 13, wherein the video display is in communication with a memory device that stores the one or more images to be displayed on the video display.
